(19) United States
(12) Patent Application Publication
(10) Pub. No.: US 2024/0194456 A1
(43) Pub. Date: Jun. 13, 2024

(54) FILM FORMING METHOD AND SUBSTRATE PROCESSING APPARATUS

(71) Applicant: Tokyo Electron Limited, Minato-ku, Tokyo (JP)

(72) Inventors: Hiroki MURAKAMI, Nirasaki City, Yamanashi (JP); Shuichiro SAKAI, Nirasaki City, Yamanashi (JP)

(21) Appl. No.: 18/552,957

(22) PCT Filed: Mar. 25, 2022
(86) PCT No.: PCT/JP2022/014361

§ 371 Date: Sep. 28, 2023

(30) Foreign Application Priority Data
Mar. 31, 2021 (JP) 2021-062225
Mar. 23, 2022 (JP) 2022-046794

(51) Int. Cl. H01J 37/32; C23C 16/40; C23C 16/455; C23C 16/52; H01L 21/02

(52) U.S. Cl. CPC H01J 37/32449; C23C 16/402; C23C 16/45553; C23C 16/52; H01L 21/02164; H01L 21/02208; H01L 21/0228; H01J 2237/332

(57) ABSTRACT

A film forming method forms a film containing at least silicon and oxygen on a substrate. The film forming method includes: a) supplying a metal containing catalyst to the substrate; b) supplying a hydrogen containing gas to the substrate; and c) supplying a silicon precursor containing silanol to the substrate.

### TECHNICAL FIELD

The present disclosure relates to a film forming method and a substrate processing apparatus.

### BACKGROUND

For example, a film forming method of forming a silicon-based film on a substrate has been known.

Patent Document 1 discloses a method of depositing a silicon dioxide thin film, the method including a step of applying a gas-phase reactant pulse containing a metal precursor into a chamber with a reactant to form a substantially single molecular layer of the metal precursor on a substrate, and a step of applying a gas-phase reactant pulse containing a silicon precursor into the chamber with the reactant to react the silicon precursor with the metal precursor on the substrate.

### PRIOR ART DOCUMENTS

### Patent Documents

Patent Document 1: Japanese laid-open publication No. 2010-010686

In the step of reacting the silicon precursor with the metal precursor on the substrate, there are cases where the film formation amount is not saturated with respect to the supply time of the silicon precursor. Thus, there is a possibility of decreased uniformity in the film formed on the substrate.

In one aspect, the present disclosure provides a film forming method and a substrate processing apparatus for improving uniformity.

### SUMMARY

According to one aspect of the present disclosure, there is provided a film forming method of forming a film containing at least silicon and oxygen on a substrate including a) supplying a metal-containing catalyst to the substrate, b) supplying a hydrogen-containing gas to the substrate, and c) supplying a silicon precursor containing silanol to the substrate.

According to the present disclosure, it is possible to provide a film forming method and a substrate processing apparatus to improve uniformity.

### BRIEF DESCRIPTION OF DRAWINGS

FIG. 1 is a schematic diagram illustrating a configuration example of a substrate processing apparatus according to the present embodiment.

FIG. 2 is a time chart illustrating an example film forming process according to the present embodiment.

FIG. 3 is a time chart illustrating an example film forming process according to a first reference example.

FIG. 4 is an example graph illustrating results of average film thickness, film thickness uniformity in a substrate, and film thickness uniformity between substrates in the film forming processes according to the present embodiment and the reference example.

FIG. 5A is a diagram illustrating example film thickness distribution according to the present embodiment.

FIG. 5B is a diagram illustrating example film thickness distribution according to the first reference example.

FIG. 6 is an example graph illustrating results of secondary ion mass spectrometry of a film formed by the film forming process according to the present embodiment.

FIG. 7 is an example graph illustrating results of average film thickness in the film forming process.

FIG. 8 is a time chart illustrating another example film forming process according to the present embodiment.

FIG. 9 is a time chart illustrating still another example film forming process according to the present embodiment.

FIG. 10 is a time chart illustrating a further example film forming process according to the present embodiment.

FIG. 11 is an example graph illustrating results of average film thickness and film thickness uniformity in a substrate W in the film forming process.

FIG. 12 is a time chart illustrating yet another example film forming process according to the present embodiment.

### DETAILED DESCRIPTION

Hereinafter, embodiments for carrying out the present disclosure will be described with reference to the drawings. In each drawing, the same reference numerals may be given to the same components, and redundant descriptions may be omitted.

### [Substrate Processing Apparatus]

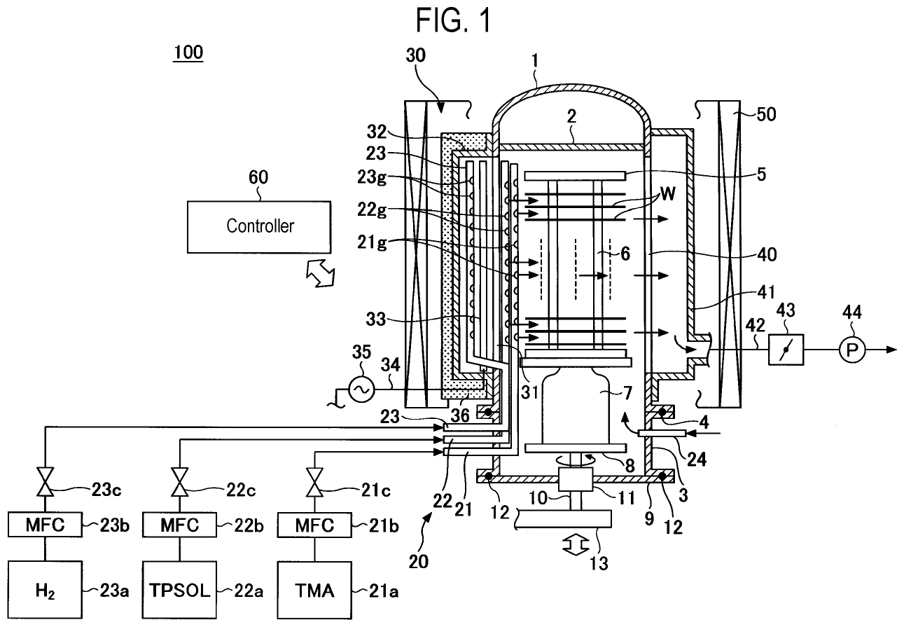

A substrate processing apparatus 100 according to the present embodiment will be described with reference to FIG. 1. FIG. 1 is a schematic diagram illustrating a configuration example of the substrate processing apparatus 100 according to the present embodiment.

The substrate processing apparatus 100 includes a cylindrical processing container 1 with a ceiling and an open bottom. The entire processing container 1 is made of, for example, quartz. A ceiling plate 2, which is made of quartz, is provided near the top inside the processing container 1, and a region under the ceiling plate 2 is sealed. A metallic manifold 3, which is molded into a cylinder, is connected to an opening at the bottom of the processing container 1 via a seal member 4 such as an O-ring.

The manifold 3 supports the bottom of the processing container 1, and a wafer boat 5, in which a large number (e.g., 25 to 150) of semiconductor wafers (hereinafter referred to as “substrate W”) are mounted in multiple stages, is inserted into the processing container 1 from below the manifold 3. As such, the large number of substrates W are accommodated substantially horizontally inside the processing container 1 at intervals along the vertical direction. The wafer boat 5 is made of, for example, quartz. The wafer boat 5 has three rods 6 (two are illustrated in FIG. 1), and the large number of substrates W are supported by grooves (not illustrated) formed in the rods 6.

The wafer boat 5 is mounted above a table 8 via a heat reservoir 7, which is made of quartz. The table 8 is supported on a rotating shaft 10, which penetrates a metallic (stainless steel) lid 9 that opens or closes an opening at the bottom of the manifold 3.

A magnetic fluid seal 11 is provided around a penetrating portion of the rotating shaft 10 to airtightly seal and rotatably support the rotating shaft 10. A seal member 12 is provided between a peripheral portion of the lid 9 and the bottom of the manifold 3 to maintain the airtightness in the processing container 1.

The rotating shaft 10 is provided at the tip of an arm 13, which is supported by an elevating mechanism (not illustrated) such as, for example, a boat elevator, and the wafer boat 5 and the lid 9 are integrally moved up and down and are inserted into or separated from the processing container 1. In addition, the table 8 may be fixed at the side of the lid 9, such that the substrates W may be processed without rotating the wafer boat 5.

Further, the substrate processing apparatus 100 includes a gas supplier 20 that supplies predetermined gases such as a processing gas and a purge gas into the processing container 1.

The gas supplier 20 includes gas supply pipes 21 to 24. The gas supply pipes 21, 22 and 23 are made of, for example, quartz, and inwardly penetrate a sidewall of the manifold 3 and are bent upward to extend vertically. A plurality of gas holes 21g, 22g and 23g are formed at a predetermined interval in vertical portions of the gas supply pipes 21, 22 and 23 over a vertical length corresponding to the wafer supporting range of the wafer boat 5. Each of the gas holes 21g, 22g and 23g discharges a gas in the horizontal direction. The gas supply pipe 24 is made of, for example, quartz, and is formed as a short quartz pipe provided to penetrate the sidewall of the manifold 3.

The vertical portion (i.e., vertical portion formed with the gas holes 21g) of the gas supply pipe 21 is located in the processing container 1. A metal-containing catalyst gas is supplied to the gas supply pipe 21 from a gas source 21a via a gas pipe. The gas pipe is provided with a flow controller 21b and an on-off valve 21c. Thus, the metal-containing catalyst gas from the gas source 21a is supplied into the processing container 1 via the gas pipe and the gas supply pipe 21.

Here, the gas source 21a supplies the metal-containing catalyst gas to create a metal catalyst single molecular layer on a surface of the substrate W. Further, the metal-containing catalyst gas includes a gas of a metal, semimetal, or compound thereof having Lewis acid properties. Specifically, for example, an organic, inorganic, or halide precursor gas containing Al, Co, Hf, Ni, Pt, Ru, W, Zr, Ti, B, Ga, In, Zn, Mg, Ta may be used as the metal-containing catalyst. In addition, a metal catalyst may be a backing with exposed Al, Co, Hf, Ni, Pt, Ru, W, Zr, Ti, B, Ga, In, Zn, Mg, Ta. In the following description, the metal-containing catalyst gas is described as a trimethylaluminum (TMA) gas.

A vertical portion (i.e., a vertical portion formed with the gas holes 22g) of the gas supply pipe 22 is located in the processing container 1. A silicon precursor gas is supplied to the gas supply pipe 22 from a gas source 22a via a gas pipe. The gas pipe is provided with a flow controller 22b and an on-off valve 22c. Thus, the silicon precursor gas from the gas source 22a is supplied into the processing container 1 via the gas pipe and the gas supply pipe 22.

Here, the gas source 22a supplies the silicon precursor gas containing silanol. For example, a TPSOL gas, triethylsilanol, methyl bis(tert-pentoxy)silanol, or tris(tert-butoxy)silanol may be used as the silicon precursor gas. In the following description, the silicon precursor gas is described as a TPSOL(tris(tert-pentoxy)silanol) gas.

A vertical portion (i.e., vertical portion formed with a gas holes 23g) of the gas supply pipe 23 is located in a plasma generation space to be described below. A hydrogen-containing gas is supplied to the gas supply pipe 23 from a gas source 23a via a gas pipe. The gas pipe is provided with a flow controller 23b and an on-off valve 23c. Thus, the hydrogen-containing gas from the gas source 23a is supplied to the plasma generation space via the gas pipe and the gas supply pipe 23, and is plasmaized in the plasma generation space to supply hydrogen radicals into the processing container 1.

Here, the gas source 23a supplies the hydrogen-containing gas. For example, a gas containing at least hydrogen (H) or deuterium (D) such as a H₂ gas, D₂ gas, H₂O gas, NH₃ gas, silicon hydride gas, PH₃ gas, B₂H₆ gas, or hydrocarbon gas may be used as the hydrogen-containing gas. In the following description, the hydrogen-containing gas is described as a H₂ gas.

In addition, the substrate processing apparatus 100 has been described as a plasma processing apparatus that generates hydrogen radicals from a hydrogen-containing gas to supply them to the substrate W in the processing container 1, but is not limited thereto. The substrate processing apparatus 100 may be a substrate processing apparatus in which the substrate W in the processing container 1, which has been heated to a desired temperature, is supplied with a hydrogen-containing gas (e.g., NH₃ gas) from the gas supply pipe 23 to undergo a thermal processing.

A purge gas is supplied to the gas supply pipe 24 from a purge gas source (not illustrated) via a gas pipe. The gas pipe (not illustrated) is provided with a flow controller (not illustrated) and an on-off valve (not illustrated). Thus, the purge gas from the purge gas source is supplied into the processing container 1 via the gas pipe and the gas supply pipe 24. For example, an inert gas such as argon (Ar) or nitrogen (N₂) may be used as the purge gas. In addition, a case where the purge gas is supplied from the purge gas source into the processing container 1 via the gas pipe and the gas supply pipe 24 has been described, but the present disclosure is not limited thereto, and the purge gas may be supplied from any of the gas supply pipes from 21 to 23.

A plasma generation mechanism 30 is formed on a part of a sidewall of the processing container 1. The plasma generation mechanism 30 plasmaizes the hydrogen-containing gas (e.g., H₂ gas) to generate hydrogen (H) radicals.

The plasma generation mechanism 30 includes a plasma partition wall 32, a pair of plasma electrodes 33 (one is illustrated in FIG. 1), a feeding line 34, a radio frequency power supply 35, and an insulation protective cover 36.

The plasma partition wall 32 is airtightly welded to an outer wall of the processing container 1. The plasma partition wall 32 is made of, for example, quartz. The plasma partition wall 32 has a concave cross sectional shape and covers an opening 31 formed in the sidewall of the processing container 1. The opening 31 is vertically elongated to cover all the substrates W supported in the wafer boat 5 in the vertical direction. The gas supply pipe 23 for discharging the hydrogen-containing gas (e.g., H₂ gas) is arranged in an inner space, which is defined by the plasma partition wall 32 and communicates with the interior of the processing container 1, i.e., in the plasma generation space.

The pair of plasma electrodes 33 (one is illustrated in FIG. 1) have an elongated shape, respectively, and are arranged on opposite outer wall surfaces of the plasma partition wall 32 to face each other along the vertical direction. Each plasma electrode 33 is held by, for example, a holder (not illustrated) provided on the side surface of the plasma partition wall 32. The feeding line 34 is connected to the bottom of each plasma electrode 33.

The feeding line 34 electrically connects each plasma electrode 33 to the radio frequency power supply 35. In the illustrated example, the feeding line 34 is connected at one end thereof to the bottom of each plasma electrode 33 and at the other end thereof to the radio frequency power supply 35.

The radio frequency power supply 35 is connected to the bottom of each plasma electrode 33 via the feeding line 34, and supplies radio frequency power of, for example, 13.56 MHz to the pair of plasma electrodes 33. Thus, the radio frequency power is applied to the plasma generation space defined by the plasma partition wall 32. The hydrogen-containing gas (e.g., H₂ gas) discharged from the gas supply pipe 23 is plasmaized in the plasma generation space to which the radio frequency power has been applied, and the generated hydrogen radicals are supplied to the interior of the processing container 1 through the opening 31.

The insulation protective cover 36 is provided outside the plasma partition wall 32 to cover the plasma partition wall 32. A coolant passage (not illustrated) is provided in an inner portion of the insulation protection cover 36, and the plasma electrodes 33 are cooled by flowing a coolant such as a cooled nitrogen (N₂) gas through the coolant passage. Further, a shield (not illustrated) may be provided between the plasma electrodes 33 and the insulation protective cover 36 to cover the plasma electrodes 33. The shield is made of, for example, a good conductor such as a metal, and is grounded.

An exhaust port 40 for the evacuation of the processing container 1 is provided on a sidewall portion of the processing container 1 facing the opening 31. The exhaust port 40 is vertically elongated to correspond to the wafer boat 5. An exhaust port cover member 41, which is molded into a U-shaped cross section, is provided on a portion of the processing container 1 corresponding to the exhaust port 40 to cover the exhaust port 40. The exhaust port cover member 41 extends upward along the sidewall of the processing container 1. An exhaust pipe 42 for evacuating the processing container 1 is connected to a lower portion of the exhaust port cover member 41 through the exhaust port 40. The exhaust pipe 42 is connected to an exhaust device 44, which includes a pressure control valve 43 for controlling the internal pressure of the processing container 1, a vacuum pump, and the like. The interior of the processing container 1 is evacuated by the exhaust device 44 via the exhaust pipe 42.

Further, a cylindrical heating mechanism 50 for heating the processing container 1 and the substrates W inside the processing container 1 is provided to surround the outer periphery of the processing container 1.

Further, the substrate processing apparatus 100 includes a controller 60. The controller 60 controls, for example, the operation of each part of the substrate processing apparatus 100 such as, for example, the supply/stop of each gas by the opening/closing of the on-off valves 21c to 23c, the flow rates of gases by the flow controllers 21b to 23b, and the evacuation by the exhaust device 44. Further, the controller 60 controls, for example, the On/Off of radio frequency power by the radio frequency power supply 35 and the temperature of the substrates W by the heating mechanism 50.

The controller 60 may be, for example, a computer or the like. Further, a computer program that executes the operation of each part of the substrate processing apparatus 100 is stored in a storage medium. The storage medium may be, for example, a flexible disk, a compact disk, a hard disk, a flash memory, a DVD, or the like.

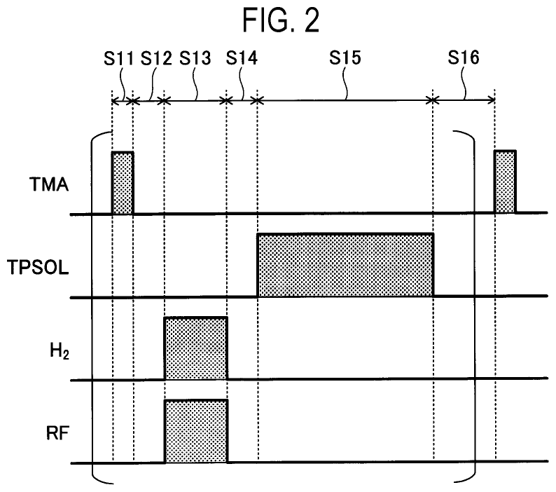

Next, an example film forming process by the substrate processing apparatus 100 will be described. FIG. 2 is a time chart illustrating an example film forming process according to the present embodiment. In the film forming process according to the present embodiment, a film containing at least silicon and oxygen is formed on the substrate W. Here, a case where a SiO₂ film or metal-containing SiO₂ film is formed will be described by way of example.

The film forming process according to the present embodiment as illustrated in FIG. 2 is a process of forming a SiO₂ film or metal-containing SiO₂ film on the substrate W by defining step S11 of supplying a metal-containing catalyst gas (TMA gas), step S12 of purging, step S13 of supplying a hydrogen-containing gas (H₂ gas), step S14 of purging, step S15 of supplying a silicon precursor gas (TPSOL gas), and step S16 of purging as one cycle, and repeating the cycle a predetermined number of times. In addition, in FIG. 2, one cycle is illustrated within parentheses. Further, in steps S11 to S16, a N₂ gas, which is the purge gas, is constantly (continuously) supplied from the gas supply pipe 24 during the film forming process.

Step S11 of supplying the metal-containing catalyst gas is a step of supplying the metal-containing catalyst gas (TMA gas) into the processing container 1. In step S11, first, the on-off valve 21c is opened to supply the metal-containing catalyst gas into the processing container 1 from the gas source 21a through the gas supply pipe 21. Thus, the metal-containing catalyst gas is adsorbed onto the surface of the substrate W, forming a metal catalyst single molecular layer.

Step S12 of purging is a step of purging the excess metal-containing catalyst gas or the like in the processing container 1. In step S12, the on-off valve 21c is closed to stop the supply of the metal-containing catalyst gas. Thus, the purge gas constantly supplied from the gas supply pipe 24 purges the excess metal-containing catalyst gas or the like in the processing container 1.

Step S13 of supplying the hydrogen-containing gas is a step of supplying the hydrogen-containing gas (H₂ gas) into the plasma generation space. In step S13, first, the on-off valve 23c is opened to supply the hydrogen-containing gas into the plasma partition wall 32 from the gas source 23a through the gas supply pipe 23. Further, the radio frequency power RF is applied to the plasma electrodes 33 by the radio frequency power supply 35 to generate a plasma in the plasma partition wall 32. The generated hydrogen (H) radicals are supplied into the processing container 1 through the opening 31. By supplying the hydrogen (H) radicals, a modification is made to suppress the film formation amount of a SiO₂ film per cycle on the surface of the substrate W in step S15, in other words, to reduce the saturation of the film formation amount of the SiO₂ film.

Step S14 of purging is a step of purging the excess hydrogen-containing gas or the like in the processing container 1. In step S14, the on-off valve 23c is closed to stop the supply of the hydrogen-containing gas. Thus, the purge gas constantly supplied from the gas supply pipe 24 purges the excess metal-containing catalyst gas or the like in the processing container 1.

Step S15 of supplying the silicon precursor gas is a step of supplying the silicon precursor gas (TPSOL gas) into the processing container 1. In step S15, first, the on-off valve 22c is opened to supply the silicon precursor gas into the processing container 1 from the gas source 22a through the gas supply pipe 22. Thus, it reacts with the metal catalyst on the surface of the substrate W to form a SiO₂ film.

Step S16 of purging is a step of purging the excess silicon precursor gas or the like in the processing container 1. In step S16, the on-off valve 22c is closed to stop the supply of the silicon precursor gas. Thus, the purge gas constantly supplied from the gas supply pipe 24 purges the excess silicon precursor gas or the like in the processing container 1.

By repeating the above cycle, a desired thickness of SiO₂ film or metal-containing SiO₂ film is formed on the substrate W.

In addition, step S11 of supplying the metal-containing catalyst gas (TMA gas), step S13 of supplying the hydrogen-containing gas (H₂ gas), and step S15 of supplying the silicon precursor gas (TPSOL gas) have been described as being sequentially (non-simultaneously) performed, but are not limited thereto. Step S11 of supplying the metal-containing catalyst gas (TMA gas), step S13 of supplying the hydrogen-containing gas (H₂ gas), and step S15 of supplying the silicon precursor gas (TPSOL gas) may partially overlap.

In addition, in the film forming process illustrated in FIG. 2, step S13 of supplying the hydrogen-containing gas has been described as a step of applying RF power to the plasma electrodes 33 to generate the hydrogen radicals from the hydrogen-containing gas, and supplying the generated hydrogen radicals into the processing container 1, thereby performing a plasma processing on the substrate W in the processing container 1, but is not limited thereto. Step S13 of supplying the hydrogen-containing gas may also be a step of supplying the hydrogen-containing gas (e.g., NH₃ gas) from the gas supply pipe 23 to the substrate W in the processing container 1, which has been heated to a desired temperature, to perform a thermal processing. In this case, it is not necessary to apply the RF power.

Here, the film forming process according to the present embodiment will be further described in comparison with film forming processes according to reference examples.

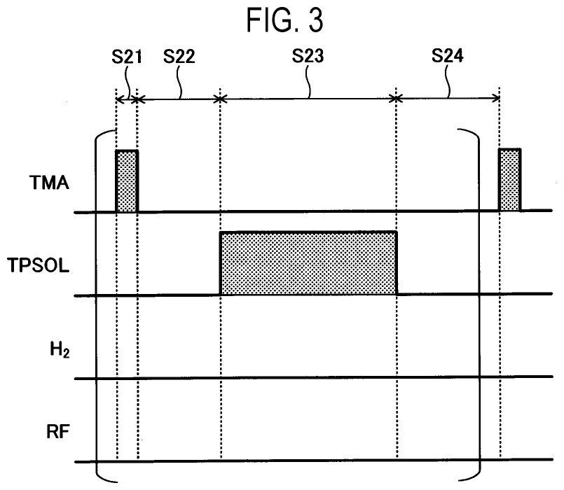

First, a film forming process according to a first reference example will be described with reference to FIG. 3. FIG. 3 is a time chart illustrating an example film forming process according to a first reference example. The film forming process according to the reference example forms a SiO₂ film or metal-containing SiO₂ film, similar to the film forming process according to the present embodiment.

The film forming process according to the first reference example as illustrated in FIG. 3 is a process of forming a SiO₂ film or metal-containing SiO₂ film on the substrate W by defining step S21 of supplying a metal-containing catalyst gas (TMA gas), step S22 of purging, step S23 of supplying a silicon precursor gas (TPSOL gas) and step S24 of purging as one cycle, and repeating the cycle a predetermined number of times. In addition, steps S21, S22, S23 and S24 illustrated in FIG. 3 are the same as steps S11, S12, S15, and S16 illustrated in FIG. 2, and redundant descriptions are omitted.

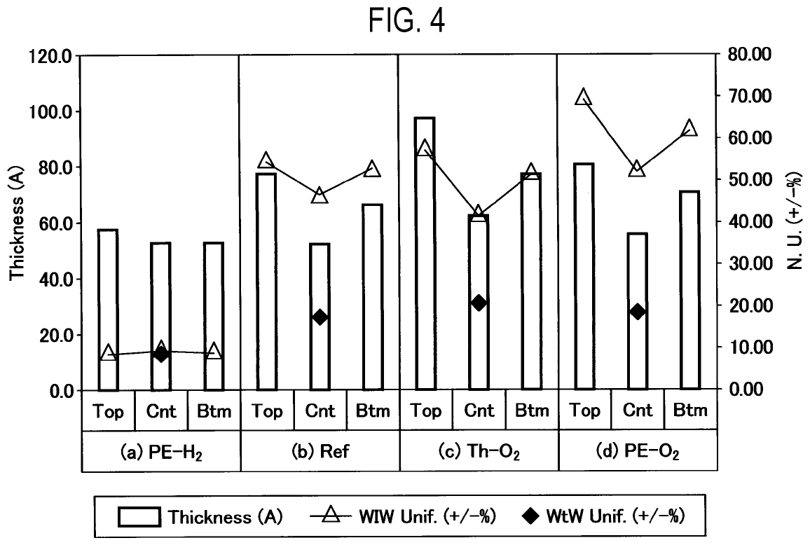

FIG. 4 is an example graph illustrating results of average film thickness, film thickness uniformity in the substrate W, and film thickness uniformity between the substrates W in the film forming processes according to the present embodiment and the reference example.

(a)PE-H₂ indicates the film formation results in the film forming process according to the present embodiment (see FIG. 2). (b) Ref indicates the film formation results in the film forming process according to the first reference example (see FIG. 3). (c) Th-O₂ indicates the film formation results in the film forming process according to a second reference example in which step S13 (see FIG. 2) is changed to a step of supplying an O₂ gas without applying RF power. (d) PE-O₂ indicates the film formation results in the film forming process according to a third reference example in which step S13 (see FIG. 2) is changed to a step of applying RF power and supplying an O₂ gas.

Further, “Top” indicates the results of the top substrate W among the substrates W stacked in multiple stages inside the processing container 1. “Cnt” indicates the results of the center substrate W of the central stage among the substrates W stacked in multiple stages inside the processing container 1. “Btm” indicates the results of the bottom substrate W among the substrates W stacked in multiple stages inside the processing container 1.

Further, the average film thickness in the substrate W of each stage is illustrated by bar graphs. The non-uniformity (N.U.) of film thickness in the substrate W of each stage (WIW Unif.) is illustrated by white triangle symbols. The non-uniformity (N.U.) of film thickness between the Top, Cnt and Btm substrates W (WtW Unif.) is illustrated by black diamond symbols.

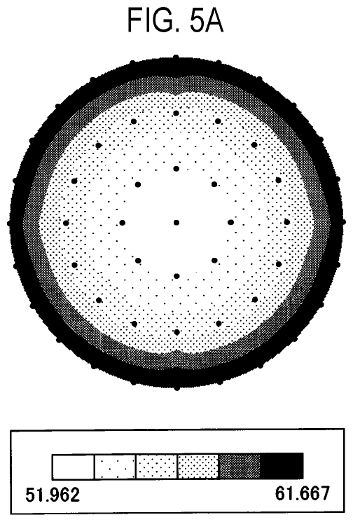

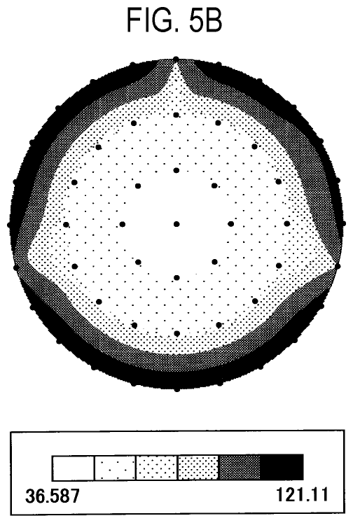

FIGS. 5A and 5B are diagrams illustrating example film thickness distributions according to the present embodiment and the first reference example. FIG. 5A illustrates example film thickness distribution of the Top substrate W in the film forming process according to the present embodiment. FIG. 5B illustrates example film thickness distribution of the Top substrate W in the film forming process according to the first reference example. Further, in FIGS. 5A and 5B, the film thickness is illustrated by the light and shade of dots.

In the film forming process according to the first reference example, as illustrated by the bar graphs in (b) of FIG. 4, the average film thickness varies between the Top, Cnt and Btm substrates W. Further, as illustrated by the diamond symbol in (b) of FIG. 4, there is significant non-uniformity of film thickness between the substrates W. That is, there occurs the non-uniformity of film thickness in the height direction of the substrates W stacked in multiple stages inside the processing container 1.

Further, in the film forming process according to the first reference example, as illustrated in FIG. 5B, the outer periphery side of the substrate W has a thicker film thickness, while the center side has a thinner film thickness. Therefore, as illustrated by the triangle symbols in (b) of FIG. 4, the non-uniformity of film thickness in the Top substrate W is significant. Further, as illustrated by the triangle symbols in (b) of FIG. 4, the Cnt and Btm substrates W exhibit the same significant non-uniformity of film thickness. That is, there occurs the non-uniformity of film thickness in the radial direction in the substrate W.

This is because, in the substrate processing apparatus 100, as illustrated in FIG. 1, where a plurality of substrates W are processed simultaneously in a batch process, a processing gas is supplied to the substrate W in a side flow manner, so that the film formation rate is higher and the film thickness is thicker on the outer periphery side of the substrate W, while the film formation rate is slower and the film thickness is thinner on the center side. Further, the film forming process according to the first reference example shows that the film formation amount of the SiO₂ film is not saturated in step S23 of supplying the silicon precursor gas (TPSOL gas).

In both the film forming process according to the second reference example in which an O₂ gas is supplied (see (c) in FIG. 4) and the film forming process according to the third reference example in which RF power is applied and an O₂ gas is supplied (see (d) of FIG. 4), there occurs the non-uniformity of film thickness in the height direction of the substrates W stacked at multiple stages as well as in the radial direction in the substrate W, similar to the film forming process according to the first reference example (see (b) of FIG. 4). In other words, an improvement in the uniformity of film thickness was not observed regardless of whether the O₂ gas is supplied, or the RF power is applied during the supply of the O₂ gas.

On the other hand, in the film forming process according to the present embodiment, as illustrated by the bar graphs in (a) of FIG. 4, there is a smaller variation in the average film thickness between the substrates W stacked in multiple stages. Further, as illustrated by the diamond symbol in (a) of FIG. 4, there is an improvement in the uniformity of film thickness between the substrates W.

Further, in the film forming process according to the present embodiment, as illustrated in FIG. 5A, a variation in film thickness between the outer periphery side and the center side of the substrate W is small. Therefore, as illustrated by the triangle symbols in (a) of FIG. 4, there is an improvement in the uniformity of film thickness in the Top substrate W. Further, as also illustrated by the triangle symbols in (a) of FIG. 4, the Cnt and Btm substrate W also exhibit an improvement in the uniformity of film thickness therein.

This is because the addition of step S13 of supplying the hydrogen-containing gas allows for the surface modification of the substrate W, enabling the control of the film formation amount saturation of the SiO₂ film. Thus, even with the configuration of supplying the processing gas to the substrate W in a side flow manner, in step S15 of supplying the silicon precursor gas (TPSOL gas), the saturation of the film formation amount of the SiO₂ film may be achieved, which may reduce a variation in film thickness between the outer peripheral side and the center side of the substrate W and may improve the uniformity of film thickness. Further, for the substrates W stacked in multiple stages, in step S15 of supplying the silicon precursor gas (TPSOL gas), the saturation of the film formation amount of the SiO₂ film may be achieved, which may reduce a variation in film thickness between the substrates W and may improve the uniformity of film thickness.

Further, in the film forming process according to the present embodiment, the SiO₂ film may be formed without using an oxidant such as O₃ and O₂, so that it is possible to prevent the oxidation of a metal film, for example, when forming the SiO₂ film above a metal film.

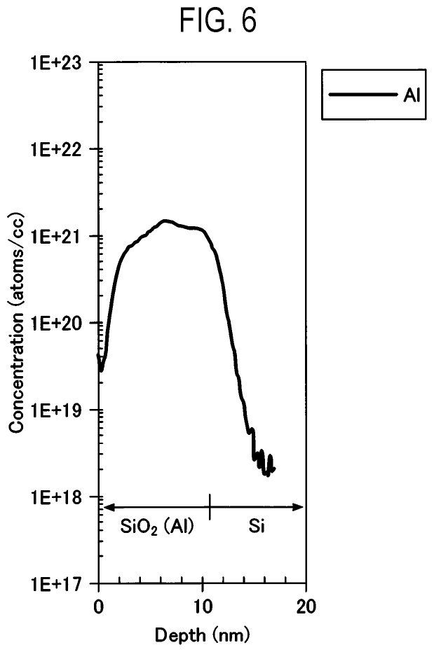

FIG. 6 is an example graph illustrating results of secondary ion mass spectrometry (SIMS) of a film formed by the film forming process according to the present embodiment. The horizontal axis represents the depth from the film surface, and the vertical axis represents the detected amount of Al.

According to the film forming process in the present embodiment, the addition of step S13 of supplying the hydrogen-containing gas may control the saturation of the film formation amount of the SiO₂ film. In other words, the film formation amount of the SiO₂ film per cycle may be controlled. Thus, by reducing the film formation amount of the SiO₂ film per cycle, it is possible to increase the frequency of supplying the metal-containing catalyst gas, and as illustrated in FIG. 6, it is possible to increase the amount of Al element contained in the SiO₂ film. Thus, it is possible to form a metal-containing SiO₂ film.

Further, it is possible to form a HfSiO film or ZrSiO film by using a metal-containing catalyst gas containing Hf or Zr.

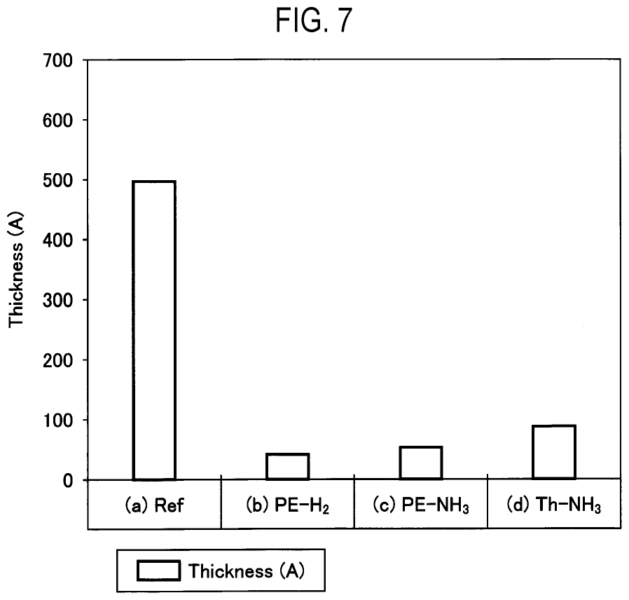

FIG. 7 is an example graph illustrating the results of average film thickness in the film forming process. FIG. 7 illustrates the average film thickness of the SiO₂ film formed on the substrate W by each process by bar graphs. (a) Ref indicates the film formation results in the film forming process according to the first reference example (see FIG. 3). (b) PE-H₂ indicates the film formation results in the film forming process (see FIG. 2). Here, this shows the film formation results in a case where, in step S13, a H₂ gas is used as the hydrogen-containing gas and hydrogen radicals, generated from the hydrogen-containing gas by applying RF power, are supplied to the substrate W in the processing container 1. Further, (c) PE-NH₃ indicates other film formation results in the film forming process (see FIG. 2). Here, this shows the film formation results in a case where, in step S13, instead of the H₂ gas, a NH₃ gas is used as the hydrogen-containing gas and hydrogen radicals, generated from the hydrogen-containing gas by applying RF power, are supplied to the substrate W in the processing container 1. (d) Th-NH₃ indicates other film formation results in the film forming process (see FIG. 2). Here, this shows the film formation results in a case where, in step S13, a NH₃ gas is used as the hydrogen-containing gas, and a thermal processing is performed by supplying the hydrogen-containing gas to the substrate W in the processing container 1, which has been heated to a desired temperature, without applying RF power.

As illustrated in FIG. 7 illustrating the comparison of (a) Ref and (b) PE-H₂, in (b) PE—H₂, the film formation amount of the SiO₂ film is reduced compared to (a) Ref. In other words, in (b) PE—H₂, the addition of step S13 of supplying the hydrogen-containing gas leads to the surface modification of the substrate W and the control of the film formation amount saturation of the SiO₂ film.

Further, in (c) PE-NH₃, the film formation amount of the SiO₂ film is reduced compared to (a) Ref. In other words, in (c) PE-NH₃, even when the NH₃ gas is used as the hydrogen-containing gas in step S13, the surface of the substrate W is modified to control the saturation of the film formation amount of the SiO₂ film, similar to (b) PE—H₂.

Further, in (d) Th-NH₃, the film formation amount of the SiO₂ film is reduced compared to (a) Ref. In other words, in (c) PE-NH₃, even when the NH₃ gas is used as the hydrogen-containing gas in step S13 and even when the plasma processing is replaced with a thermal processing, the surface of the substrate W is modified to control of the saturation of the film formation amount of the SiO₂ film, similar to (b) PE—H₂.

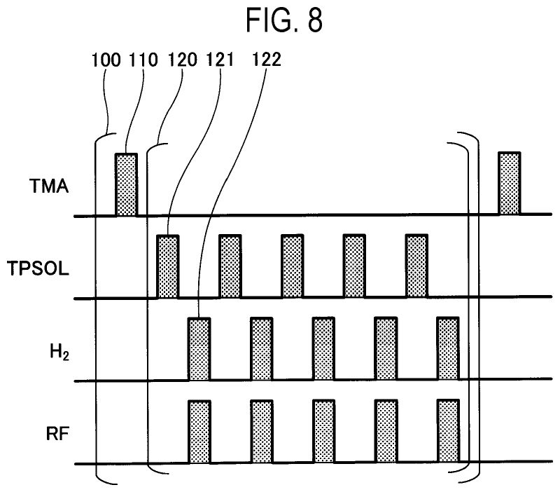

In addition, the time chart of the film forming process according to the present embodiment is not limited to that illustrated in FIG. 2. Other examples of film forming processes by the substrate processing apparatus 100 will be described. A related description will be made with reference to FIGS. 8 to 10 and 12. FIGS. 8 to 12 are time charts illustrating other examples of film formation processes according to the present embodiment.

The film forming process illustrated in FIG. 8 is a process of forming a SiO₂ film or metal-containing SiO₂ film on the substrate W by defining step 110 of supplying a metal-containing catalyst gas (TMA gas) and step 120 of repeating, a predetermined number of cycles, step 121 of supplying a silicon precursor gas (TPSOL gas) and step 122 of supplying a hydrogen-containing gas (H₂ gas) as one cycle 100, and repeating the cycle 100 a predetermined number of times. In addition, a purging step may be included before and after each gas supply step. In addition, in the example illustrated in FIG. 8, in step 122 of supplying the hydrogen-containing gas, RF power is applied to the plasma electrodes 33 during the supply of the hydrogen-containing gas (H₂ gas) to generate hydrogen radicals from the hydrogen-containing gas, and the generated hydrogen radicals are supplied into the processing container 1.

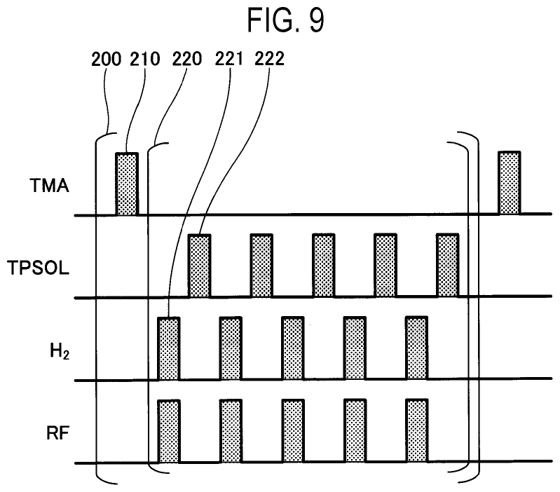

The film forming process illustrated in FIG. 9 is a process of forming a SiO₂ film or metal-containing SiO₂ film on the substrate W by defining step 210 of supplying a metal-containing catalyst gas (TMA gas) and step 220 of repeating, a predetermined number of cycles, step 221 of supplying a hydrogen containing gas (H₂ gas) and step 222 of supplying a silicon precursor gas (TPSOL gas) as one cycle 200, and repeating the cycle 200 a predetermined number of times. In addition, a purging step may be included before and after each gas supply step. In addition, in the example illustrated in FIG. 9, in step 221 of supplying the hydrogen-containing gas, RF power is applied to the plasma electrodes 33 during the supply of the hydrogen-containing gas (H₂ gas) to generate hydrogen radicals from the hydrogen-containing gas, and the generated hydrogen radicals are supplied into the processing container 1.

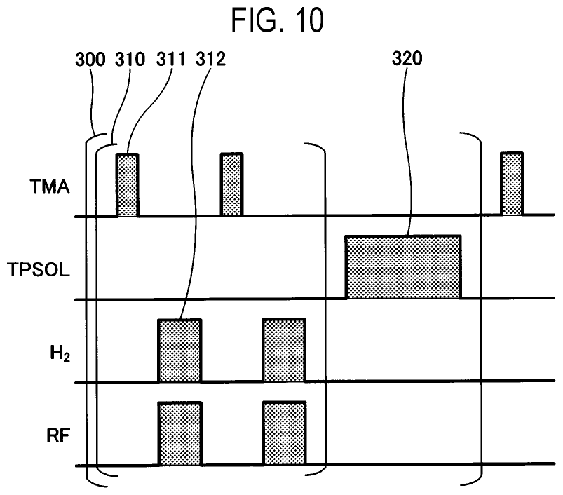

The film forming process illustrated in FIG. 10 is a process of forming a SiO₂ film or metal-containing SiO₂ film on the substrate W by defining step 310 of repeating, a predetermined number of cycles, step S311 of supplying a metal-containing catalyst gas (TMA gas) and step S312 of supplying a hydrogen containing gas (H₂ gas), and step S320 of supplying a silicon precursor gas (TPSOL gas) as one cycle 300, and repeating the cycle 300 a predetermined number of times. In addition, a purging step may be included before and after each gas supply step. In addition, in the example illustrated in FIG. 10, in step 312 of supplying the hydrogen-containing gas, RF power is applied to the plasma electrodes 33 during the supply of the hydrogen-containing gas (H₂ gas) to generate hydrogen radicals from the hydrogen-containing gas, and the generated hydrogen radicals are supplied into the processing container 1.

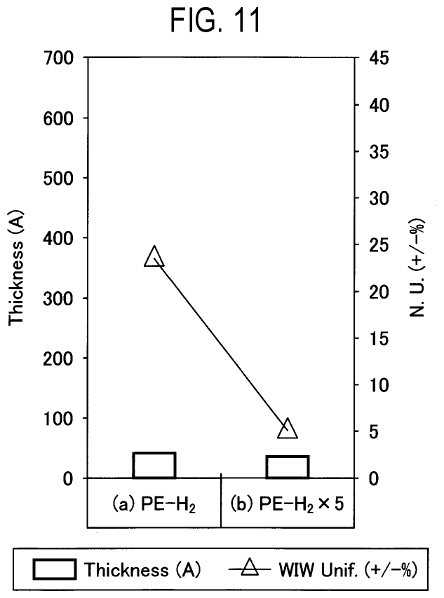

Here, the effects of the film forming process illustrated in FIG. 10 will be described with reference to FIG. 11. FIG. 11 is a graph illustrating results of average film thickness and film thickness uniformity in the substrate W in the film forming process. In FIG. 11, the average film thickness of the SiO₂ film formed on the substrate W by each process is illustrated by bar graphs. Further, the non-uniformity (N.U.) of film thickness in the substrate W of each stage (WIW) is illustrated by white triangle symbols. (a) PE—H₂ indicates the film formation results in the film forming process (see FIG. 2). (b) PE—H₂×5 indicates the film formation results in the film forming process (see FIG. 10). Here, step S310 is defined as repeating, five cycles, step 311 of supplying a metal-containing catalyst gas (TMA gas) and step 312 of supplying a hydrogen-containing gas (H₂ gas) 5 cycles.

As illustrated in FIG. 11, in (b) PE—H₂×5, the non-uniformity (NU) of film thickness in the substrate W (WIW) is reduced. In other words, it is possible to improve the uniformity of film thickness.

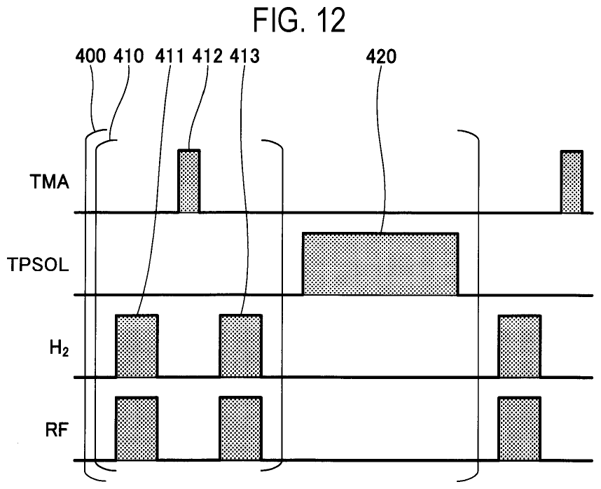

The film forming process illustrated in FIG. 12 is a process of forming a SiO₂ film or metal-containing SiO₂ film on the substrate W by defining step 410 of performing step 411 of supplying a hydrogen-containing catalyst gas (H₂ gas), step 412 of supplying a metal-containing catalyst gas (TMA gas) and step 413 of supplying a hydrogen containing gas (H₂ gas), and step 420 of supplying a silicon precursor gas (TPSOL gas) as one cycle 400, and repeating the cycle 400 a predetermined number of times. In addition, a purging step may be included before and after each gas supply step. In addition, in the example illustrated in FIG. 12, in steps 411 and 413 of supplying the hydrogen-containing gas, RF power is applied to the plasma electrodes 33 during the supply of the hydrogen-containing gas (H₂ gas) to generate hydrogen radicals from the hydrogen-containing gas, and the generated hydrogen radicals are supplied into the processing container 1.

In the film forming process illustrated in FIGS. 8 to 10 and 12, it is possible to control the saturation of the film formation amount, similar to the film forming process illustrated in FIG. 2. This allows for an improvement in the uniformity of film thickness. Further, by reducing the film formation amount per cycle, it is possible to increase the amount of Al element contained in the SiO₂ film, enabling the formation of the SiO₂ film or metal-containing SiO₂ film.

In addition, in the film forming process illustrated in FIGS. 8 to 10 and 12, steps 122, 221, 312, 411 and 413 of supplying the hydrogen-containing gas have been described as a step of applying RF power to the plasma electrodes 33 to generate hydrogen radicals from the hydrogen-containing gas, and supplying the generated hydrogen radicals into the processing container 1, thereby performing a plasma processing on the substrate W in the processing container 1, but is not limited thereto. Step 122, 221, 312, 411 and 413 of supplying the hydrogen-containing gas may also be a step of supplying the hydrogen-containing gas (e.g., NH₃ gas) from the gas supply pipe 22 to the substrate W in the processing container 1, which has been heated to a desired temperature, to perform a thermal processing. In this case, it is not necessary to apply RF power.

Although the film forming method of the present embodiment by the substrate processing apparatus 100 has been described above, the present disclosure is not limited to the above-described embodiment and the like, and various modifications and improvements are possible within the scope of the gist of the present disclosure described in the claims.

The film forming process illustrated in FIGS. 2, 8 to 10 and 12 has been described as a batch type substrate processing apparatus 100 that performs a film forming process on a plurality of substrates W, but is not limited thereto. The film forming process of the present embodiment may also be applied to a single wafer type substrate processing apparatus.

This application claims the priority based on Japanese Patent Application No. 2021-062225 filed on Mar. 31, 2021, and the entire contents of this Japanese patent application is incorporated herein by reference.

Further, this application claims the priority based on Japanese Patent Application No. 2022-046794 filed on Mar. 23, 2022, and the entire contents of this Japanese patent application is incorporated herein by reference.

### EXPLANATION OF REFERENCE NUMERALS

W: substrate, 100: substrate processing apparatus, 1: processing container, 2: ceiling plate, 3: manifold, 4: seal member, 5: wafer boat, 6: rod, 7: heat reservoir, 8: table, 9: lid, 10: rotating shaft, 20: gas supplier, 21: gas supply pipe (metal-containing catalyst supplier), 22: gas supply pipe (silicon precursor supplier), 23: gas supply pipe (hydrogen-containing gas supplier, hydrogen radical supplier), 24: gas supply pipe, 21a: gas source (metal-containing catalyst supplier), 22a: gas source (silicon precursor supplier), 23a: gas source (hydrogen-containing gas supplier, hydrogen radical supplier), 30: plasma generation mechanism (hydrogen radical supplier), 40: exhaust port, 50: heating mechanism, 60: controller

1-11. (canceled)

12. A film forming method of forming a film containing at least silicon and oxygen on a substrate, the method comprising:
a) supplying a metal-containing catalyst to the substrate;
b) supplying a hydrogen-containing gas to the substrate; and
c) supplying a silicon precursor containing silanol to the substrate.

13. The film forming method of claim 12, wherein a), b), and c) are performed non-simultaneously.

14. The film forming method of claim 13, wherein a first step of performing a), a second step of performing b) after the first step, and a third step of performing c) after the second step are repeated a plurality of times.

15. The film forming method of claim 14, wherein the metal-containing catalyst includes a metal, semimetal or compound thereof having a Lewis acid property.

16. The film forming method of claim 15, wherein the metal contained in the metal-containing catalyst includes at least one of Al, Co, Hf, Ni, Pt, Ru, W, Zr, Ti, B, Ga, In, Zn, Mg, or Ta.

17. The film forming method of claim 16, wherein b) includes generating a hydrogen radical from the hydrogen-containing gas and supplying the hydrogen radical to the substrate.

18. The film forming method of claim 17, wherein the hydrogen-containing gas includes at least one of a H₂ gas, a D₂ gas, a H₂O gas, a NH₃ gas, a silicon hydride gas, a PH₃ gas, a B₂H₆ gas, or a hydrocarbon gas.

19. The film forming method of claim 12, wherein a fourth step of performing a), a fifth step of performing b) after the fourth step, and a sixth step of performing c) after the fifth step are repeated a plurality of times.

20. The film forming method of claim 12, wherein a seventh step of performing a), and a eighth step of alternately repeating b) and c) after the seventh step are repeated a plurality of times.

21. The film forming method of claim 12, wherein a nineth step of alternately repeating a) and b) and a tenth step of performing c) after the nineth step are repeated a plurality of times.

22. The film forming method of claim 12, wherein the metal-containing catalyst includes a metal, semimetal or compound thereof having a Lewis acid property.

23. The film forming method of claim 22, wherein the metal contained in the metal-containing catalyst includes at least one of Al, Co, Hf, Ni, Pt, Ru, W, Zr, Ti, B, Ga, In, Zn, Mg, or Ta.

24. The film forming method of claim 12, wherein b) includes generating a hydrogen radical from the hydrogen-containing gas and supplying the hydrogen radical to the substrate.

25. The film forming method of claim 24, wherein the hydrogen-containing gas includes at least one of a H₂ gas, a D₂ gas, a H₂O gas, a NHs gas, a silicon hydride gas, a PH₃ gas, a B₂H₆ gas, or a hydrocarbon gas.

26. A substrate processing apparatus comprising:
a processing container configured to accommodate a substrate therein;
a metal-containing catalyst supplier configured to supply a metal-containing catalyst into the processing container;
a silicon precursor supplier configured to supply a silicon precursor containing silanol into the processing container;
a hydrogen-containing gas supplier configured to supply a hydrogen-containing gas into the processing container; and
a controller,
wherein the controller is configured to execute:
a) controlling the metal-containing catalyst supplier to supply the metal-containing catalyst to the substrate in the processing container;
b) controlling the hydrogen-containing gas supplier to supply the hydrogen-containing gas to the substrate in the processing container; and
c) controlling the silicon precursor supplier to supply the silicon precursor to the substrate in the processing container.

27. The substrate processing apparatus of claim 26, wherein the processing container accommodates a plurality of substrates to perform a processing thereon.
